(19) United States
(12) Patent Application Publication
(10) Pub. No.: US 2018/0041167 A1
(43) Pub. Date: Feb. 8, 2018

(54) Frequency converter

(71) Applicant: Sam Belkin, San Diego, CA (US)

(72) Inventor: Sam Belkin, San Diego, CA (US)

(21) Appl. No.: 15/228,978

(22) Filed: Aug. 4, 2016

(51) Int. Cl. H03D 7/12

(52) U.S. Cl. CPC H03D 7/125; H04B 1/16

(57) ABSTRACT

A linear frequency converter or mixer design that utilizes linear time-varying devices and that avoids interaction between the local oscillator (LO) current and other signals inside the mixer, thus achieving high linearity and signal purity. This mixer also uses a LO frequency at least two times lower than conventional mixers, hence improving isolation between different system partitions. This class of mixer may not require a power supply.

### CROSS-REFERENCE TO RELATED APPLICATIONS

This application claims the benefit of priority of U.S. Provisional Application No. 62/201,489, filed 5 Aug. 2015 for Sam Belkin, which is incorporated herein by reference in its entirety.

### BACKGROUND OF THE INVENTION

### 1. Field

The present invention is generally in the field of radio frequency circuitry, and specifically applies to frequency mixing technologies.

### 2. Background

In analog circuitry, a frequency mixer is also known as a “mixer,” “converter,” “combiner,” “multiplier,” and sometimes “modulator.” For the purpose of this document, all those terms are interchangeable, and the general term “mixer” shall equate to all variations in terminology. Mixer circuits are characterized by multiple (usually two) input ports at differing frequencies and at least one output port at which appears at least the sum and difference of the two inputs, and can also include the sums and differences of harmonics of the two inputs, potentially creating a complex waveform. Those many frequencies appearing in the output of the mixer are typically applied to the input of a filter of appropriate selectivity (narrow bandpass) to permit selection of the frequency(ies) most useful in the overall design, and suppression of other frequencies.

In most mixer circuits, at least one of the input frequencies is variable, or controllable, by either automated or manual means. Such control determines the output of the mixer circuit. That controllable input is usually called the local oscillator, or LO.

One problem with existing mixers is that they use nonlinear components that create distortion of the output signal, which limits the performance of the overall system.

Typical mixers are comprised of a nonlinear component or circuit to which the signal frequency and the LO frequency are simultaneously applied. The result is a form of intermodulation, as multiple signals are created when the signals of the two frequencies interact with each other. Intermodulation products can be very complex, but it will be the subsequent filter at the output port—usually a bandpass filter—that extracts the desired signal and suppresses others.

Among the simplest nonlinear components used in mixers is a diode, which produces the original frequencies as well as their sum and their difference, along with many other mixing products. Complex mixers are comprised of many individual components, and provide the circuit designer with multiple options. But simple and complex mixers use nonlinear components which, by definition, produce output characteristics that reduce the performance of the overall system.

In a typical radio circuit, the output of the antenna will usually contain many carrier frequencies generated by multiple signals received from multiple transmitters. Early radio designers learned that it is difficult to manage and manipulate such a complex signal, but relatively easier to convert the desired signal to a standardized carrier frequency that is manageable, enabling the subsequent circuitry to be optimized for performance at that single frequency. In radios, that standardized frequency is usually called the Intermediate Frequency (IF). In the mixer, those multiple frequencies are combined with a controllable signal, the LO, which is varied to control the output of the mixer to generate that IF standard, among other mixer products. If a selective filter follows the mixer, then controlling the LO can shift the desired carrier frequency to that which will pass the selective filter, the output of which then becomes the IF, the signal to which the rest of the system has been tuned. That tuning circuit is usually followed by various forms of demodulation (extraction of a carrier's content) and amplification.

In a simple amplitude modulation (AM) radio, the antenna simultaneously receives many broadcast stations (frequencies), but the combination of an LO, a mixer, and a filter permits the user to tune the system to the desired station.

Obviously, the mixer—the frequency converter—is a critical component of any radio, and of many other types of electronic circuits; the mixer has a major influence upon the overall performance of the system.

Existing mixer architectures appearing in the prior art (market, professional papers, patent filings) are generally combinations of compromises that require the designer to deal with various permutations of cost, size, reliability, performance, complexity, power dissipation, and other potentially problematic issues. Worse, imperfect mixer performance multiplies problems in subsequent circuitry. The mixer, therefore, is fundamentally important in radio frequency circuit design, and can have a profound effect upon overall system merit.

A mixer design is characterized by cost, size, and power dissipation, and also by these performance specifications:

CONVERSION LOSS is a measure of the efficiency of the mixer in providing frequency translation from the input signal to the output signal. Conversion loss of a mixer is equal to the ratio of the IF single sideband output power to the RF input power, expressed as a positive number in dB. The lower the loss, the more efficient the mixer. In many designs, one or another of the mixer's inputs and/or outputs are amplified within the overall mixer circuit, thus enabling the management of conversion loss and even providing conversion GAIN, but amplification by its nature introduces noise and other artifacts.

CONVERSION COMPRESSION is a measure of the maximum RF input signal for which the mixer will provide linear operation in terms of constant conversion loss. This specification enables the comparison of dynamic range for various mixers, and the maximum input power.

ISOLATION is a measure of the circuit balance within the mixer. When isolation is high, the “leakage” or “feed through” between mixer ports will be small, and the inverse is true. Typically, mixer isolation falls off with frequency due to the imbalance of any transformer, lead inductance, and capacitive imbalance between mixer circuit components such as diodes.

DYNAMIC RANGE is the signal power range over which a given mixer design operates effectively without conversion compression. The conversion compression point identifies the upper limit of dynamic range; the NOISE FIGURE, the BANDWIDTH, and the level of INTERMODULATION PRODUCTS of the mixer circuit identify the lower limit of dynamic range.

INTERMODULATION distortion takes place when two RF signals simultaneously enter the mixer non-linear RF port and interact to produce modulation of either signal by the other, resulting in undesired signal artifacts. This can occur in a multiple-carrier signal environment, or when an undesired signal interferes with a desired one. Also, an imperfect mixer generates its own intermodulation distortion due to its non-linearity. The products resulting from the interaction are usually objectionable, and impose limits upon the design of the overall circuit when they fall within the frequency range of the mixer output.

INTERCEPT POINT is a commonly accepted and useful method of describing the capability of a mixer to suppress two-tone, third order intermodulation distortion, using the “third-order intercept” approach. The third-order intercept point (IP3) is a theoretical location on the output versus input line where the desired output signal (each of the two tones) and the two third-order products (each one) become equal in power, as RF input power is raised. This single mixer specification usually defines the overall performance of the mixer design, and its utility in the circuit.

The ideal frequency mixer is essentially linear, with output spectra that include fewer artifacts and noise than less ideal designs. In such an optimized design the mixing function generates fewer products or artifacts from the input and LO signals. In conventional mixer designs, LO current does flow through the device that accomplishes the mixing, and that device is typically nonlinear.

A theoretically ideal mixer will generate the desired output with no artifacts and noise, and most specifically no output energy resulting from LO currents flowing through the mixer device.

Even in an idealized mixer, there can be some products or signal artifacts due to angle cuttings. However, compared to mixers in the prior art, the idealized mixer will generate these products at a significantly lower power level, and their effect on overall system performance will be less. Mixers in the prior art are defined by the specification called the 3rd intercept point (IP3), and conventional mixers achieve an IP3 level at about 20 dBm. This single specification defines mixer performance.

The current invention is a mixer architecture that uses linear devices such as field effect transistors (FETs) as LO-controlled variable resistors, or actual variable resistors, or another linear variable device, and avoids LO current within the mixer circuit, thus achieving significantly higher IP3 numbers. This parameter supports very aggressive circuit designs not previously possible, and overall system performance not previously achievable.

### 3. Prior Art

In the professional literature, commercial market, and in the files of various patent offices, there exist hundreds of different mixer designs. All seek to produce a commercially viable combination of linearity, cost, conversion loss, reliability, and similar factors, but none use the architecture of the present invention, and none provide performance of the parallel channel mixing circuit used in an embodiment of the present invention. All designs that use nonlinear devices produce an IP3 parameter that is well below the performance of the present invention.

Many excellent mixer configurations have been developed. However, evolving systems can benefit from clarity that is not possible with nonlinear devices, and the inherent problems of conventional mixers put an ever-increasing burden on the circuit designer, requiring compromises in critical areas. Ordinary design compromises are generally not necessary when the present invention is used.

### 4. Objectives of the Present Invention

The present invention provides circuit designers with a cost-effective mixer that has an IP3 (third order intercept point), and also higher order IPs, substantially improved over the capabilities of conventional mixer technologies.

### BRIEF SUMMARY OF THE PRESENT INVENTION

The present invention is a mixer or frequency converter that uses field effect transistors, resistors, or other linear devices/circuits as controllable mixing devices, in circuits that prevent local oscillator (LO) currents from appearing in the mixer, thus providing features, functions, and performance not achieved by conventional designs.

### BRIEF DESCRIPTION OF THE SEVERAL DRAWINGS

FIG. 1 shows a common mixer.

FIG. 2 describes a mixer circuit using Field Effect Transistors (FETs).

FIG. 3 describes a simple embodiment of the present invention.

FIG. 4 shows the gate voltage of parallel FETS as a mixer.

FIG. 5 shows currents through FETs.

FIG. 6 shows input/output waveforms.

FIG. 7 shows a switching parallel mixer.

FIG. 8 shows anti-parallel diode technology.

FIG. 9 shows a parallel FET mixer with example component values.

FIG. 10 shows the gate voltage vs output current for a parallel FET mixer.

FIG. 11 shows a simulated output signal.

FIG. 12 shows two time varying channels.

FIG. 13 shows imaginary mixer plots.

FIG. 14 shows a differential version of the parallel time-varying imaginary harmonic mixer.

FIG. 15 shows an IQ imaginary harmonic mixer.

### DETAILED DESCRIPTION OF THE INVENTION

Mixers are very important and complex parts of RF and microwave systems. They provide frequency conversion and mixing as required by the system architecture. Unfortunately, mixers are non-linear devices by definition and therefore produce parasitic or spurious signals. The goal is a mixer that will mix signals linearly without introducing spurious components in the output.

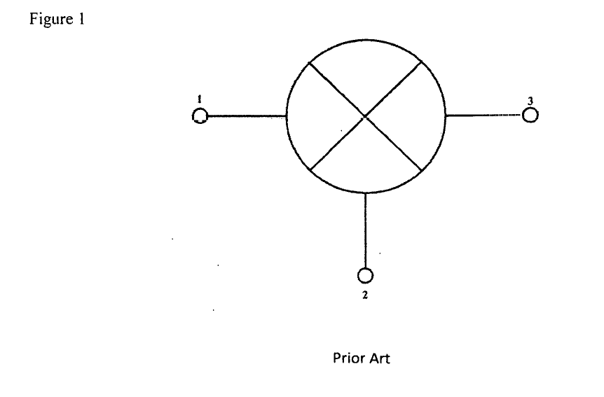

Traditional mixers per FIG. 1 are non-linear devices. However, the frequency mixing device can be absolutely linear in the amplitude-frequency domain. For example, a simple resistor may work well as a mixer if its parameters are somehow changed in the time domain.

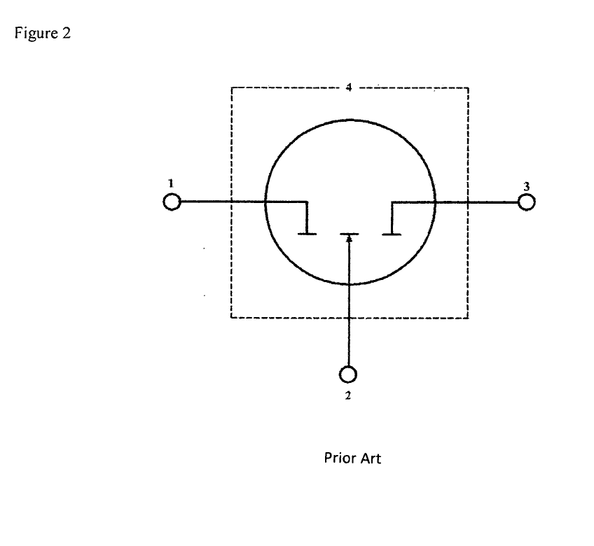

This concept applies to a new class of mixer that performs as a linear device. A variable resistor can be a good mixer, and one realization of this idea is a field effect transistor (FET) configured to operate as a variable resistor per FIG. 2. Many known mixers are based on this idea, but all of them produce artifacts in their output because electrical currents of all the participating frequencies and from the power supply are flowing through the mixer circuit, thus creating a variety of sum, difference, multiple, and submultiple signals at the mixer's output.

The present invention is a mixer in which only the RF and IF signals flow through the mixer circuit. Since there is no LO current flowing through the mixer, LO-related signal products are minimized. Of course, some of them may appear because any mixing process involves cutting input signals at some angles. This is natural to the mixing process and cannot be avoided.

As less non-linear cutting is involved in the mixing process, fewer undesired signals will be generated, and they will have relatively low amplitudes. To achieve this requires a mixing device that is as linear as possible. Linear resistance devices are good examples, and the best voltage controlled resistance devices are FET transistors. There are many different kinds of FETs, of which some can be very effective as linear variable-resistance components in mixers.

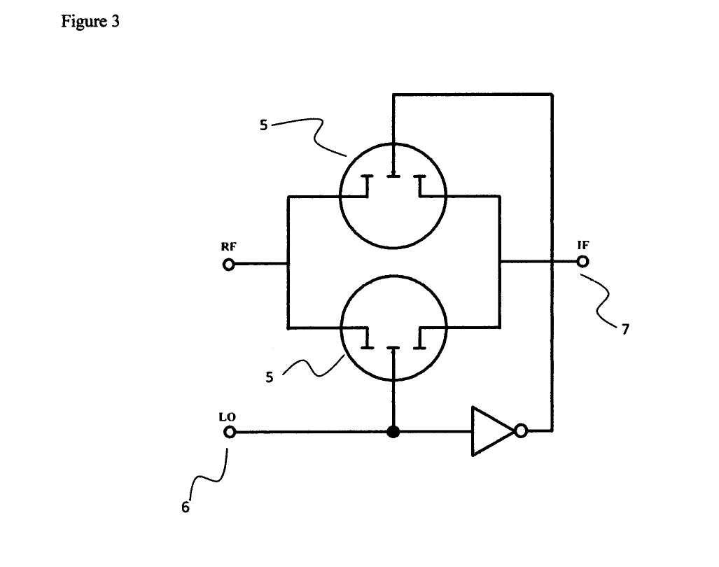

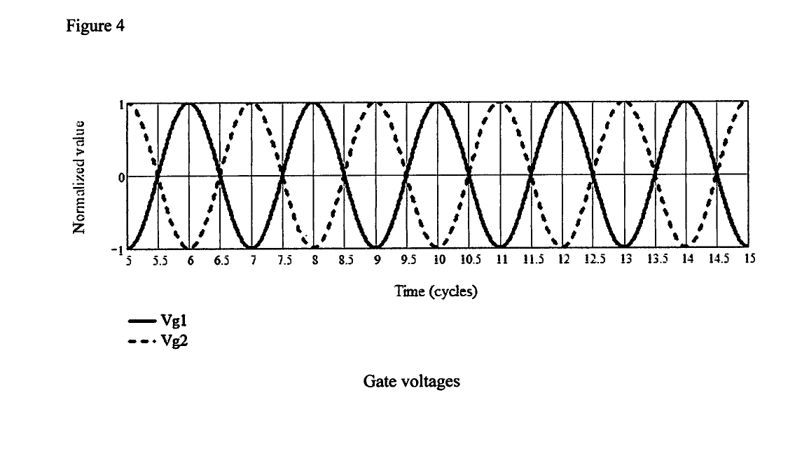

Frequency mixing requires a non-linear circuit, and there may be several non-linearities involved in the process. Consider an FET acting as a linear resistor that can change its resistance by application of a control voltage. Changing an FET's resistance is a linear process in the amplitude-frequency domain. However, it may be linear or non-linear in the time domain. Therefore, the circuit in FIG. 3 may be used, and such a variation is within the scope of the present invention. The gate voltages in FIG. 4 apply.

This type of electronic system employs a device with only one non-linear characteristic, and it ensures very low non-linear products. The intrinsic non-linearity of the semiconductor device is not involved in the creation of the unwanted products, and this is a major improvement compared to traditional mixing circuits. In the case of this optimized design, only the cutoff angle is the contributing factor, and that process can be evaluated with the Fourier mathematical conversion. However, it is a well-known phenomenon, first predicted by Lagrange in the early 1800s, and later by Gibbs, that show the limitations of the Fourier transform technique. Even without the Fourier math, it is clear that frequency conversion based upon a linear device produces less undesired signals compared to the traditional non-linear device.

Consider a simple mixing system based on the described linear principle. A single FET transistor can work as the adjustable resistor even without applying the source-drain voltage. When the channel resistance varies with the LO signal, the output will include mixing products of the RF and LO signals. This is a simple example of linear frequency mixing. This circuit has another important positive property: no LO signal current flows through the mixer's input and output circuits. Therefore, the output will have only the frequency components produced by resistive change, and nothing from the intrinsic non-linearity of the semiconductor device itself. The fact that the LO signal does not flow through the mixer's circuits ensures that the output will not include significant combinations of the LO with either input or output.

The best Gilbert-cell based mixer of today's electronics can do a good job of mixing, but in addition to mixed signals, the output includes many undesired frequencies of which most are produced by the non-linearity of the semiconductor device(s). Usage of the linear resistive mixing element can reduce these unwanted products, and there are other ways to improve the mixing.

One of the fundamental problems in mixing technology is the LO voltage. It is the most powerful signal in the circuit and it produces the most powerful products. By eliminating that powerful source of unwanted signals, the result is a mixer with much improved output. With an FET mixer it is possible to eliminate the LO currents from the circuit.

Another method to further reduce the LO current effect on mixer performance is by connecting two equal channels of controlled resistance, in which the conductance of each FET is controlled by opposite phase LO signals, and each FET will conduct every one half of the cycle of the LO. Therefore, the RF signals will be transferred to the IF output twice per LO period. This implies IF=RF±2·LO

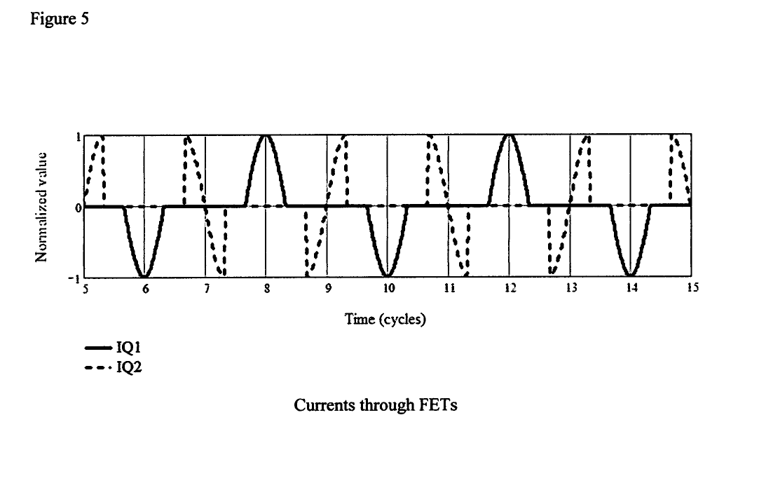

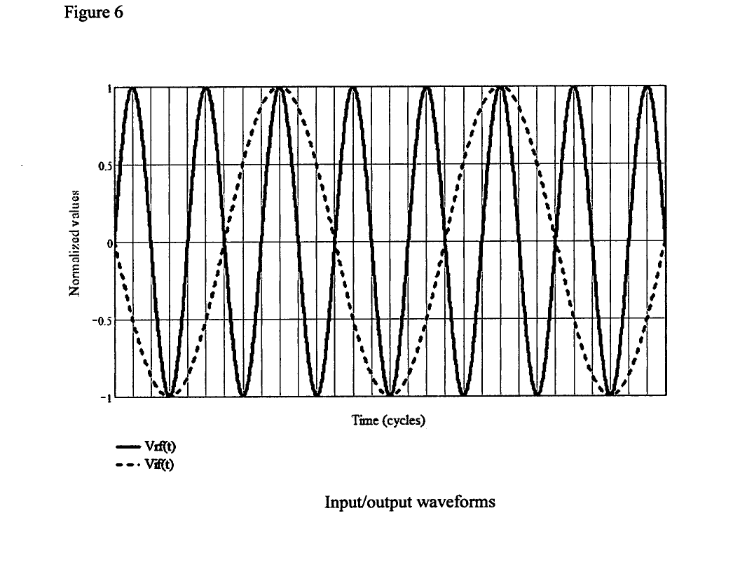

In a well-balanced bridge such as that in an embodiment of the present invention, no currents at the LO frequency flow through the mixer's circuit, as in FIG. 5. Physically, there is also no LO current because the gate circuit is isolated from the source-drain path, with input/output waveforms as shown in FIG. 6.

| | |
|---|---|
| Define time scale in cycles | t := 5, 5.01 . . . 15 |
| Normalized RF input frequency | F_{rf} := 0.75 |
| Normalized LO frequency | Fₗₒ : = 0.5 |
| FET threshold voltage | Vt := 0.5 |
| Define input signals | V_{rf}(t) := cos(2π F_{rf} t) |
| | V_{g1}(t) := cos [(2π Fₗₒ) t] |
| | Vg2(t) := cos(2π Fₗₒ t + π) |
| Define currents through FETs | IQ1(t) := if(Vg1(t) > Vt, Vrf(t), 0) |
| | IQ2(t) := if(Vg2(t) > Vt, Vrf(t), 0) |
| Output IF signal | Vif(t) := cos[(2 · Flo − Frf) · 2 · π · t] |

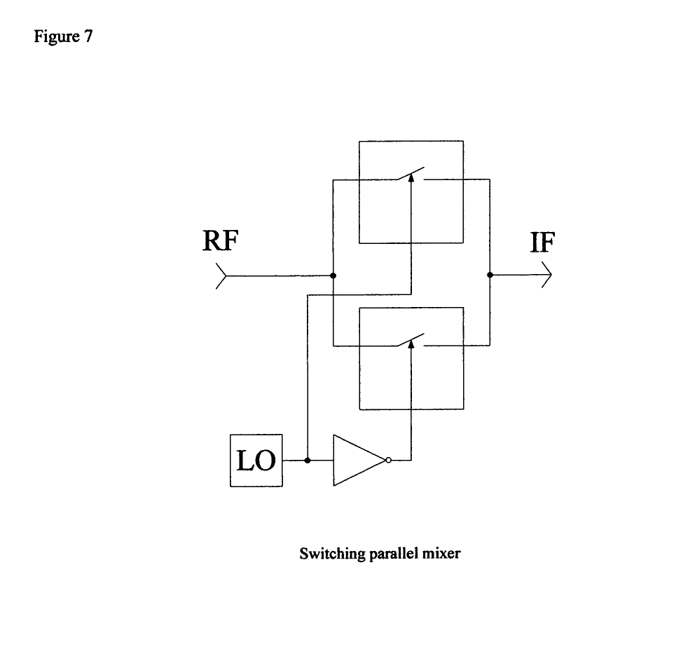

The resistive mixer is not the only possible solution for linear mixing. Another embodiment of the present invention is the parallel switching technology shown in FIG. 7.

This configuration uses two RF switches with good RF performance. In this embodiment of the present invention, the third order intercept point value can be up to 86 dBm, which is far higher than mixers available in today's technology (they are typically limited to about 20 dBm). Such a mixer, together with dynamically tunable filtering technology, can provide a third order intercept point exceeding 135 dBm, a performance point once considered impossible but made achievable by the present invention.

A mixer's quality is determined by its ability to mix RF and LO signals with minimal distortions resulting in high linearity, but the mixer is intrinsically a non-linear device. There are ways in which a mixer can be made more linear, as described in the technical literature. The ideal mixer must be linear in the amplitude and frequency domain. However, it can be non-linear in the other domains that will not produce the amplitude and frequency distortion that results in spurs in the output spectrum.

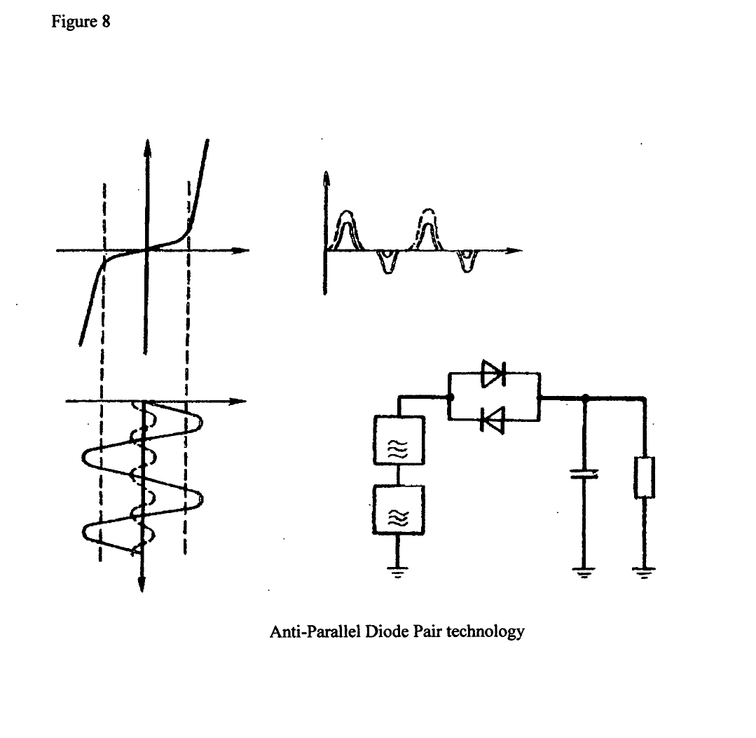

As mentioned, one way to improve frequency performance is to change the LO frequency and reduce the LO currents into the circuit. In addition to the method previously described, this can be achieved with subharmonic mixers that use a frequency at just a fraction of the required LO. The very simple example of this technology, within the scope of the present invention, is the Anti-Parallel Diode Pair (APDP) configuration shown in FIG. 8.

Volt-ampere characteristics of such inverse-paralleled diodes can be described by equation:

i=A*v+B*v³

where A and B are constants; v=(Vrf)*Cos(ω_{rf}t)+(Vlo)*Cos(ωₗₒt)

Considering that the capacitor is shorting the high frequency component and (Vrf)<<(Vlo) the solution is:

i=(¾)*B*(Vrf)*[(Vlo)²]*Cos(2ωlo−ωrf)t

This formula shows that the output current has no component with RF or LO frequencies, indicating that such mixers do not detect RF or LO voltages. However, this mixer still produces some unwanted output products of applied signals.

The electronic component that contributes least to amplitude variation is the resistor, which can be (and is) used as a mixing device. Any device that is linear in the amplitude and frequency domain element may be a mixer, because the circuit can introduce a time-varying property to the otherwise absolutely linear device. Changing resistance of the resistor in the time domain will enable the resistor to mix signals. This is a well-known phenomenon and technical publications on this subject are available.

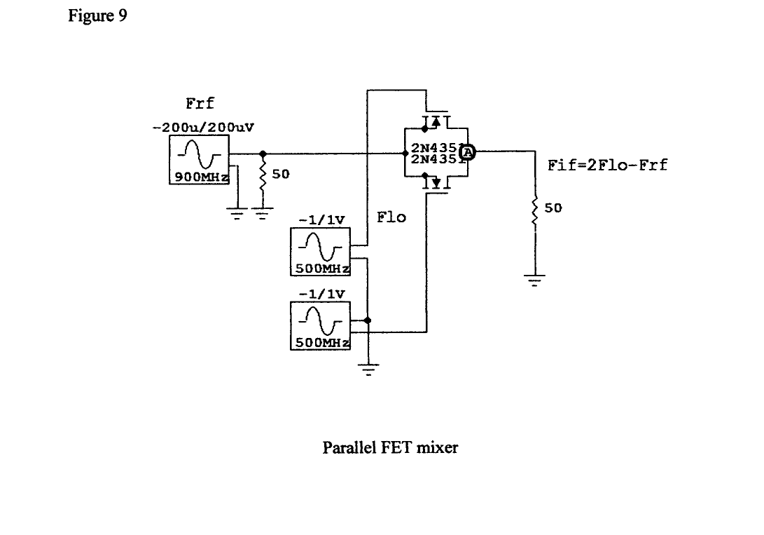

One of the possible realizations of resistive mixers, with example values, is shown in FIG. 9. In this embodiment, two equal FET's are connected in parallel to create a highly linear mixer.

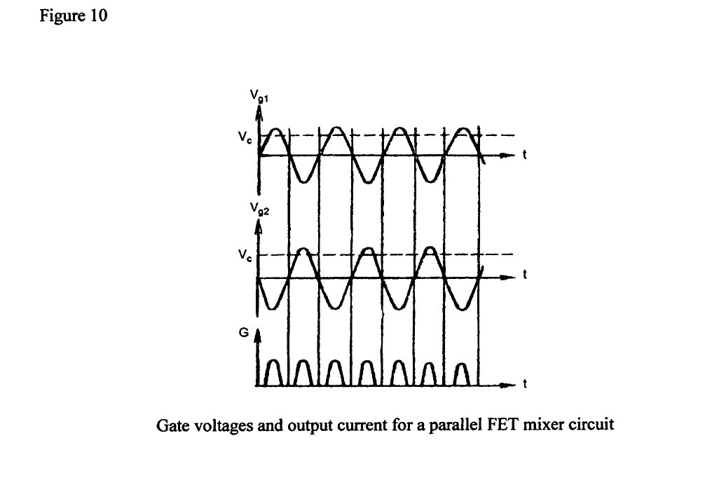

The gate voltages in FIG. 10 are in opposite phase and they produce the total conductance changes, presented on the lower plot. It is double the gate frequency so the output frequency will be equal to Fₒᵤₜ=Fᵢₙ±2·F_{LO}

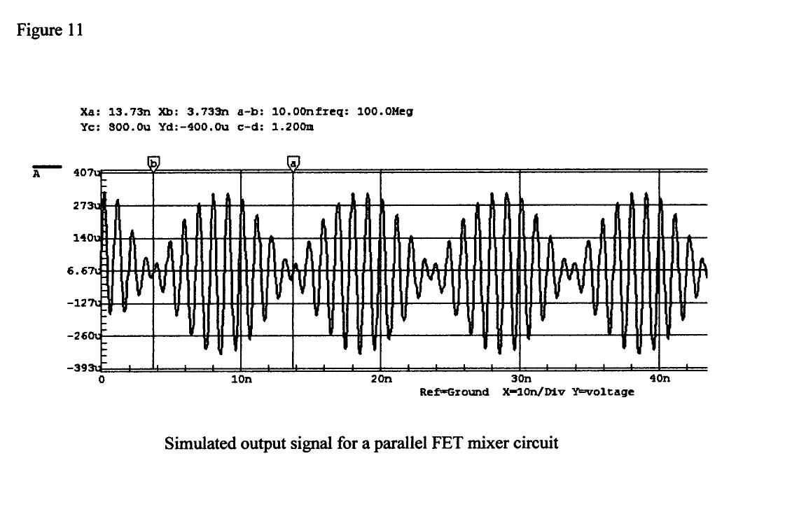

The simulated output waveform for the parallel FET mixer is shown in FIG. 11, in which only a product from two mixed frequencies can be seen.

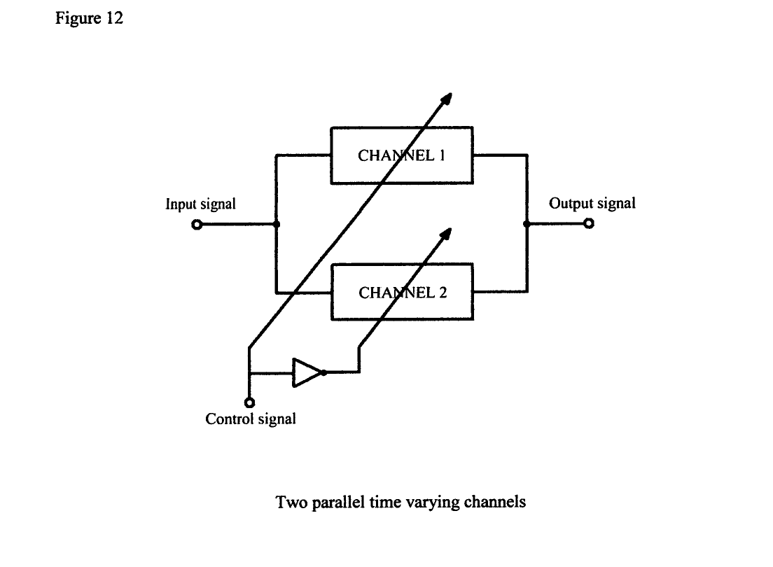

The Imaginary Harmonic mixing embodiment of the present invention can be generalized with the interpretation presented in FIG. 12. Two time-varying channels, CHANNEL 1 and CHANNEL 2, are depicted, controlled by the LO signal. These channels can be of the varied-resistance or time-varying gain (switching) class.

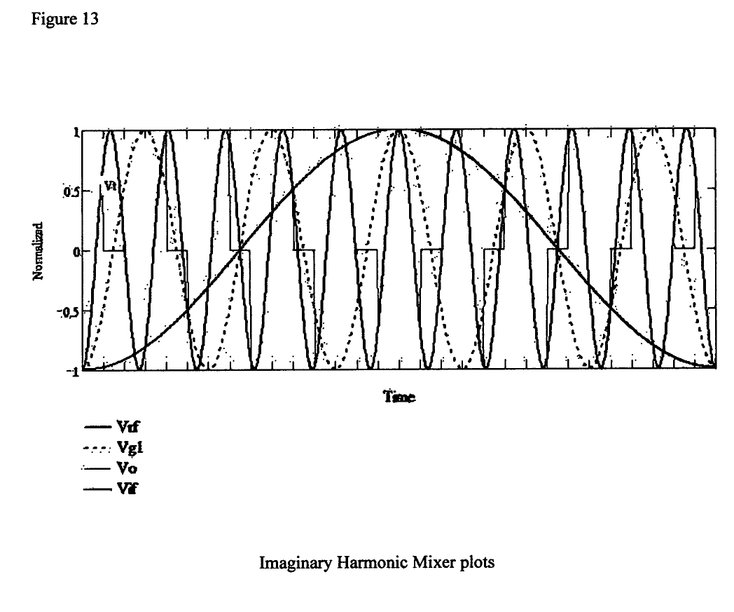

The output is filtered by a low-pass or band-pass filter and the simulated corresponding plots for this mixing technology are shown in FIG. 13.

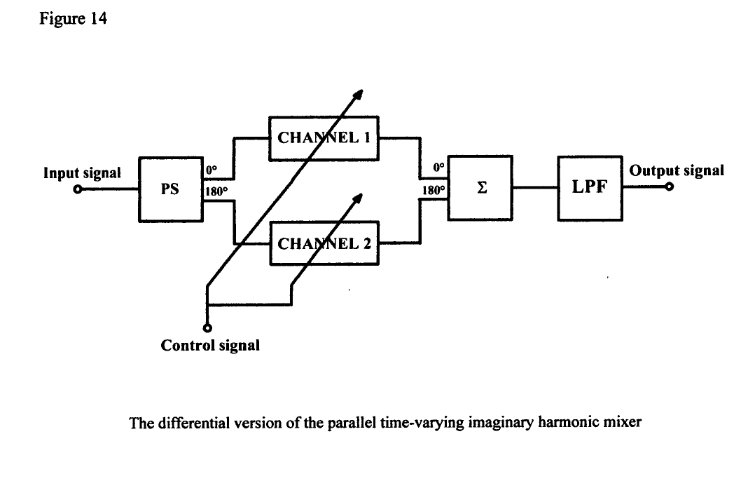

The discussed time-varying mixer topology can also be realized in the differential form as presented in FIG. 14. Here PS is the phase shifter, which may be any of several known devices that produce the required 180 degree phase shift, such as a balun.

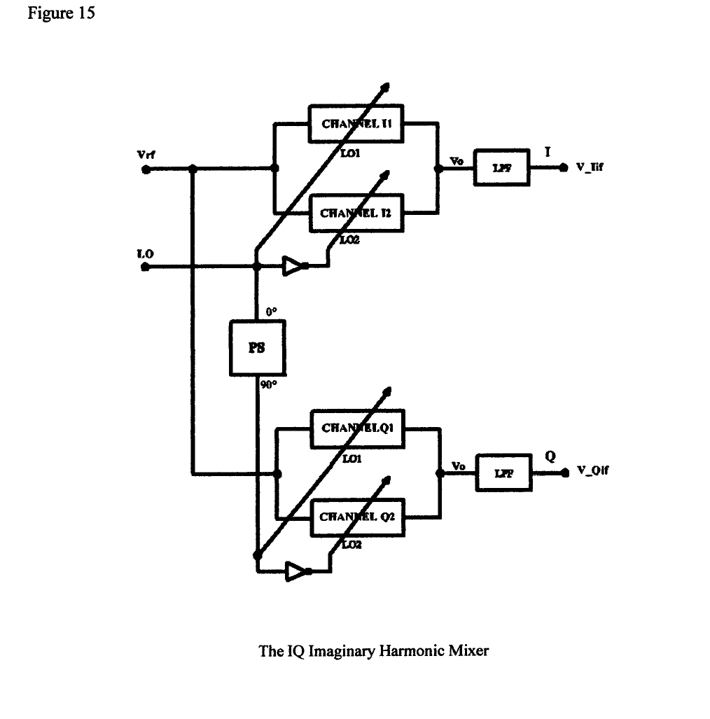

Time-varying topology can also be used for quadrature IQ mixers, modulators and demodulators. One of the possible realizations of the IQ IHM mixer is shown in FIG. 15.

Mixers based upon time-varying are the most linear due to very low dependence of their parameters to the levels of the input and output signals applied to the mixer. This approach will ensure the highest possible linearity of the mixer and the lowest level of intermodulation products at its output. IPn values will be improved, including the third order IP3 level which is the most important in narrow band communications.

Moreover, this technology allows configurations in which LO currents do not flow through the mixer circuit, eliminating signals generated by interactions that include the LO current, thus making the output spectrum clearer compared to other mixers.

Better linearity and clearer output spectrum are the major parameters required for advanced communication technology. This implies the wide usage of the present invention for wireless communications, radars, test equipment, and other electronic circuits of the future.

Imaginary Harmonic Mixers have one more serious advantage: the LO frequency is at least two times lower than in conventional mixers, permitting much better isolation between the LO and other parts of the circuit. For instance, in direct conversion receivers this approach will dramatically improve isolation between receiver input and LO, thus reducing the DC generated at the mixer's output. In Dynamically Tuned Filtering technology, lower LO amplitude will similarly provide better isolation between the LO and other parts of the system, useful because in such systems the LO frequency may be close to the input frequency.

Like conventional mixers, Imaginary Harmonic Mixers can use attenuators at the ports that will optimize the converter performance and simplify the ports matching.

Therefore, the present invention is a mixer (combiner, multiplier, etc.) that uses linear devices which are varied in the time domain to maximize linearity. The preferred embodiment of the present invention uses field effect transistors as variable resistors, controlled by a local oscillator (LO), with a circuit that minimizes the effect of the LO upon the output of the mixer.

1. A frequency converter circuit comprising:
a first and a second controllable switch, with each controllable switch structured to receive at least one frequency input signal;
a controllable local oscillator that generates a control signal and sends it to a first and a second output circuit, the first output circuit communicating with the first controllable switch to control an opening and a closing of the first controllable switch in response to a change in the control signal; and
one or more linear in amplitude domain channels that mix said at least one frequency input signal with said at least one frequency input signal from said controllable local oscillator to produce at least one frequency output signal.

2. The frequency converter circuit according to of claim 1, wherein each of said one or more linear-in-amplitude domain channels has at least one resistance, wherein said resistance is at least one field effect transistor, at least one variable gain amplifier, at least one variable gain attenuator, or at least one switch.

3. The frequency converter circuit according to claim 1, further comprising means for adjusting the phase of said at least one frequency input signal from said controllable local oscillator.

4. The frequency converter circuit according to claim 1, further comprising one or more filters that suppress undesired signals.

5. The frequency converter circuit according to claim 1, wherein said at least one frequency input signal comprises a plurality of frequency input signals from said controllable local oscillator, each having a unique phase with respect to the phase of other frequency input signals from said controllable local oscillator.

6. The frequency converter circuit according to claim 1, wherein current does not flow through said frequency converter circuit.

7. The frequency converter circuit according to claim 1, wherein said linear in amplitude domain channels are defined by the equation F_{OUT}=F_{IN}+/−2·F_{LO}.

8. A frequency converter apparatus structured to receive at least one frequency input signal, the frequency converter apparatus comprising:
a first and a second controllable switch, with each controllable switch structured to receive the at least one frequency input signal, with each controllable switch structured to open and close in response to changes in a control signal;
a local oscillator that generates the control signal and sends it to a first and a second output circuit, the first output circuit communicating with the first controllable switch to control an opening and a closing of the first controllable switch in response to a change in the control signal, with the second output circuit connected through an inverter to the second controllable switch to control an opening and a closing of the second controllable switch in response to the control signal; and
a single output communicating with both the first and second output circuits, with a single output signal containing both a sum of and a difference between the at least one frequency input signal and the control signal.

9. The frequency converter apparatus of claim 8, where each gain-control channel is comprised of a switch.

10. The frequency converter apparatus of claim 8, where each gain-control channel is comprised of a field effect transistor.

11. The frequency converter apparatus of claim 8, where each gain-control channel is comprised of a controllable attenuator.

12. A frequency converter apparatus structured to receive at least one frequency input signal, the frequency converter apparatus comprising:
an input port that is structured to receive the frequency input signal;
at least two gain-control channels structured to receive the frequency input signal;
a local oscillator communicating with the at least two gain-control channels, the local oscillator controlling a gain and a frequency of each of the at least two gain-control channels; and
a phase shifter communicating with the at least two gain-control channels, with an output of the at least two gain-control channels connected to produce an output.

13. The frequency converter apparatus of claim 12, where each gain-control channel is comprised of a switch.

14. The frequency converter apparatus of claim 12, where each gain-control channel is comprised of a field effect transistor.

15. The frequency converter apparatus of claim 12, where each gain-control channel is comprised of a controllable attenuator.
